(19) United States
(12) Patent Application Publication
(10) Pub. No.: US 2014/0284674 A1
(43) Pub. Date: Sep. 25, 2014

(54) SEMICONDUCTOR STORAGE DEVICE CAPABLE OF RELIEVING CAPACITOR DEFECT

(71) Applicant: KABUSHIKI KAISHA TOSHIBA, Tokyo (JP)

(72) Inventor: Hitoshi IWAI, Kamakuri-shi (JP)

(21) Appl. No.: 14/020,453

(22) Filed: Sep. 6, 2013

(30) Foreign Application Priority Data
Mar. 22, 2013 (JP) 2013-060947

(51) Int. Cl. H01L 27/115

(52) U.S. Cl. CPC H01L 27/1157
USPC 257/298

(57) ABSTRACT

According to one embodiment, a semiconductor storage device includes a first capacitor, a second capacitor, a first selector gate, and a second selector gate. The first capacitor has first and second ends, the first end is electrically connected to an input end of a clock signal. The second capacitor as a spare has third and fourth ends and is electrically connected to the input end. The first selector gate is electrically connected between the second end of the first capacitor and a first node of the voltage generating circuit. The second selector gate is connected between the fourth end of the second capacitor and the first node of the voltage generating circuit. The first and second selector gates are switched based on an output voltage of the voltage generating circuit.

### CROSS-REFERENCE TO RELATED APPLICATIONS

This application is based upon and claims the benefit of priority from Japanese Patent Application No. 2013-060947, filed Mar. 22, 2013, the entire contents of which are incorporated herein by reference.

### FIELD

Embodiments described herein relate generally to a semiconductor storage device, for example, a laminated NAND flash memory.

### BACKGROUND

It is becoming increasingly difficult to make the micropatterning of a NAND flash memory finer, and lower-cost methods that differ from those used previously are being sought. As one such method, a laminated NAND flash memory is under development.

### BRIEF DESCRIPTION OF THE DRAWINGS

FIG. 1 is a circuit diagram showing a charge pump circuit according to a first embodiment;

FIG. 2 is a perspective view schematically showing the configuration of a capacitor and a memory cell shown in FIG. 1;

FIG. 3 is a plan view schematically showing a semiconductor storage device to which the first embodiment is applied;

FIG. 4 is a perspective view showing a three-dimensional stacked structure of a nonvolatile semiconductor storage device applied to the first embodiment;

FIG. 5 is a sectional view showing a portion of FIG. 4;

FIGS. 6A to 6D are schematic sectional views along line VI-VI in FIG. 3, FIG. 6A is a sectional view schematically showing a peripheral circuit unit, FIG. 6B is a sectional view schematically showing a word line leading portion, FIG. 6C is a sectional view along line A-A in FIG. 4, and FIG. 6D is a sectional view along line B-B in FIG. 4;

FIG. 7 is a flowchart showing a test operation of the charge pump circuit shown in FIG. 1;

FIG. 8 is a circuit diagram showing a charge pump circuit according to a second embodiment;

FIG. 9 is a flowchart showing the test operation of the charge pump circuit shown in FIG. 8;

FIG. 10 is a circuit diagram showing a charge pump circuit according to a third embodiment; and

FIG. 11 is a flowchart showing the test operation of the charge pump circuit shown in FIG. 10.

### DETAILED DESCRIPTION

In general, according to one embodiment, a semiconductor storage device includes a first capacitor, a second capacitor, a first selector gate, and a second selector gate. The first capacitor includes first and second ends and the first end is electrically connected to an input end of a clock signal. The second capacitor as a spare unit includes third and fourth ends, which are electrically connected to the input end. The first selector gate is electrically connected between the second end of the first capacitor and a first node of a voltage generating circuit. The second selector gate is connected between the fourth end of the second capacitor and the first node of the voltage generating circuit. The first and second selector gates are switched based on an output voltage of the voltage generating circuit.

With increasing micropatterning and storage capacities of elements, a NAND flash memory in a three-dimensional structure called Bit-Cost Scalable (BiCS) has been developed.

A NAND flash memory needs various voltages and these voltages are generated by a charge pump circuit as a voltage generating circuit. The charge pump circuit drives a capacitor by a clock signal to output a voltage equal to a power supply voltage or higher.

A NAND flash memory in a three-dimensional structure has a plurality of flat interconnect layers constituting word lines arranged by interposing an insulating layer therebetween. The plurality of interconnect layers is considered to be used as a capacitor of the charge pump circuit.

However, the plurality of laminated interconnect layers may fail due to a short caused between interconnect layers. If a capacitor used in a charge pump circuit fails due to a short, the charge pump circuit becomes unusable, leading to a fatal defect.

Thus, in the present embodiment, a redundant circuit of a capacitor is provided to relieve a defective capacitor of a charge pump circuit.

The embodiments will be described below with reference to the drawings.

### First Embodiment

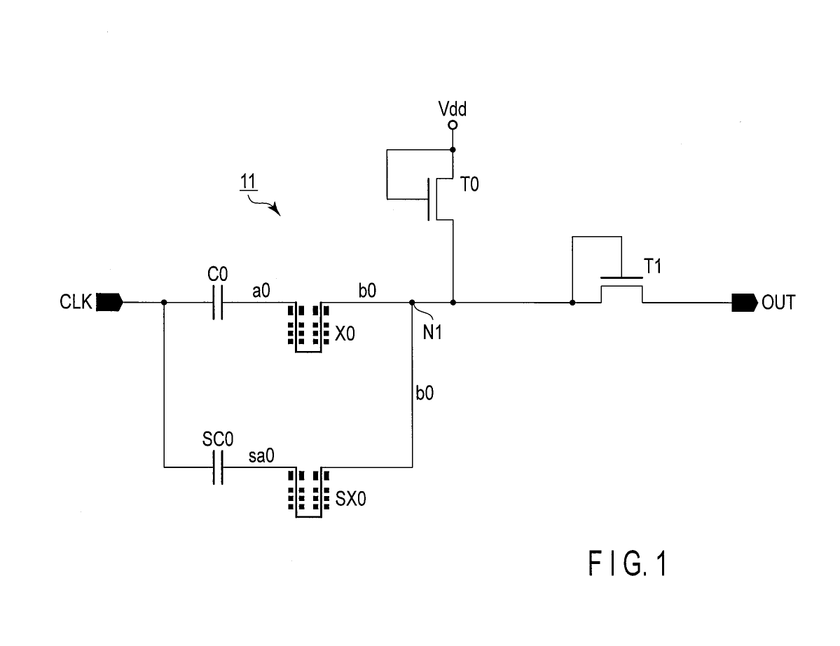

FIG. 1 relates to the first embodiment and shows a charge pump circuit 11 including a redundant circuit.

The charge pump circuit 11 includes, for example, a regular capacitor C0, a spare capacitor SC0 configuring a redundant circuit, and a switch or memory cells X0 and SX0 to switch capacitors C0 and SC0.

One end of each of capacitors C0 and SC0 is connected to a supply node of a clock signal CLK. The other end of capacitor C0 is connected to one end of memory cell X0 via an interconnect a0 and the other end of capacitor SC0 is connected to one end of memory cell SX0 via an interconnect sa0. The other ends of these memory cells X0 and SX0 are connected to a booster node N1 of the charge pump circuit 11 via an interconnect b0.

For example, an NMOS transistor T0 is connected between the booster node N1 and a supply node of a power supply Vdd. The gate of NMOS transistor T0 is connected to the supply node of the power supply Vdd. Further, an NMOS transistor T1 is connected between the booster node N1 and an output node OUT of the charge pump circuit 11. The gate of NMOS transistor T1 is connected to the booster node N1.

(Configuration of a Capacitor and a Memory Cell)

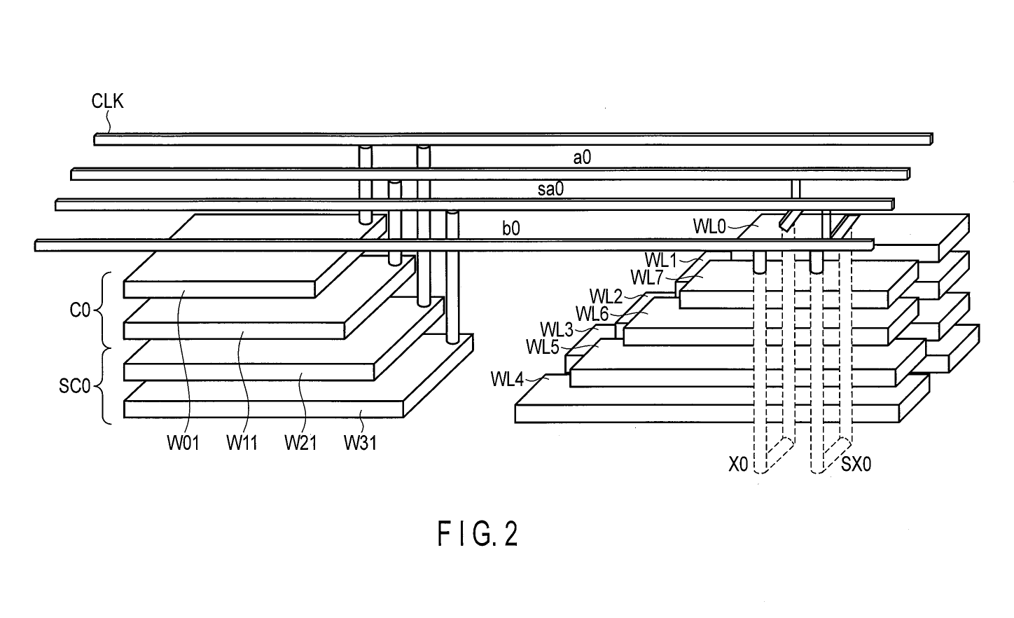

FIG. 2 schematically shows the configuration of capacitors C0 and SC0 and memory cells X0 and SX0 and the same reference numbers are attached to the same units as those in FIG. 1.

Capacitors C0 and SC0 are configured by interconnect layers constituting word lines of memory cells X0 and SX0 (hereinafter, also simply called word lines) WL0/WL7, WL1/WL6, WL2/WL5, and WL3/WL4, and interconnect layers W01 to W33. Interconnect layers WL0/WL7 to WL3/WL4 and interconnect layers W01 to W33 are each flat and stacked by insulating layers (not shown) being interposed therebetween.

Capacitor C0 is configured by interconnect layers W01 and W11 and capacitor SC0 is configured by interconnect layers W21 and W31. In this example, only four interconnect layers are shown, but interconnect layers are not limited to these interconnect layers and interconnect layers to be used for capacitors C0 and SC0 can be selected from a plurality of interconnect layers.

Like memory cells in a memory cell array described later, memory cells X0 and SX0 are formed in through-holes passing through word lines WL0/WL7 to WL3/WL4. In the case of this example, bottoms of two through-holes are linked to form a U-shape. The eight word lines WL0 to WL7 are arranged in the two through-holes and thus, NAND strings containing eight memory cells are configured. These NAND strings will be called memory cells X0 and SX0 below.

(Configuration of a Memory Cell Array)

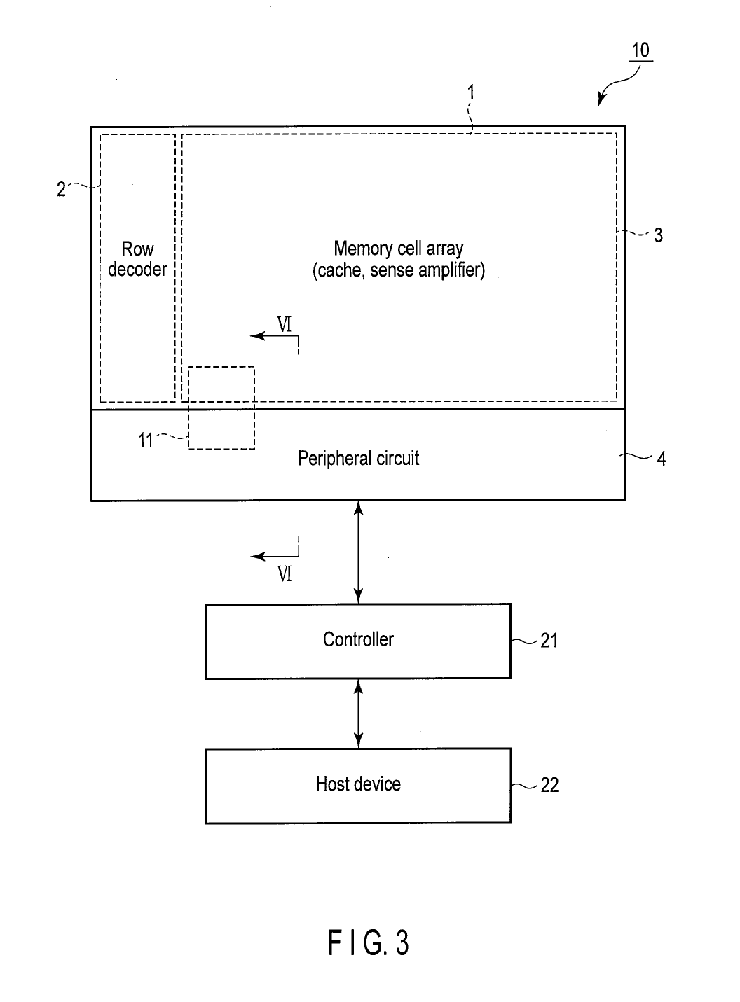

FIG. 3 schematically shows a plan view of a NAND flash memory 10 as a nonvolatile semiconductor storage device.

The NAND flash memory 10 includes a memory cell array 1, a row decoder 2, a cache and sense amplifier 3, and a peripheral circuit 4. The row decoder 2, the cache and sense amplifier 3, and the peripheral circuit 4 are formed on a substrate described later and the memory cell array 1 is formed, for example, above the cache and sense amplifier 3.

The charge pump circuit 11 is formed, for example, in the memory cell array 1 and the peripheral circuit 4. In this case, for example, a laminated interconnect layer positioned in a boundary between the memory cell array 1 and the peripheral circuit 4 is used as capacitors C0 and SC0 and memory cells in the memory cell array 1 can be used as memory cells X0 and SX0. Transistors T0 and T1 are formed in the peripheral circuit 4.

However, the formation position of the charge pump circuit 11 is not limited the above example. When, for example, memory cells X0 and SX0 dedicated to the charge pump circuit 11 are formed, capacitors C0 and SC0 and memory cells X0 and SX0 may be formed outside the memory cell array 1 near, for example, the row decoder 2.

Moreover, NAND flash memory 10 has a controller 21. The controller 21 controls whole operations of the NAND flash memory 10. The controller 21 can be connected to a host device 22, and controls the operations of the NAND flash memory in accordance with kinds of commands supplied from the host device 22.

When the memory cell array 1 is formed, the laminated interconnect layer is also formed in the periphery thereof. That is, a dummy interconnect layer is formed to prevent interference of lithography. Using the interconnect layer, capacitors C0 and SC0 and memory cells X0 and SX0 may be formed. Memory cells X0 and SX0 are not limited to the same size and configuration as those of memory cells in the memory cell array 1 and the size and configuration dedicated to the charge pump circuit may also be adopted.

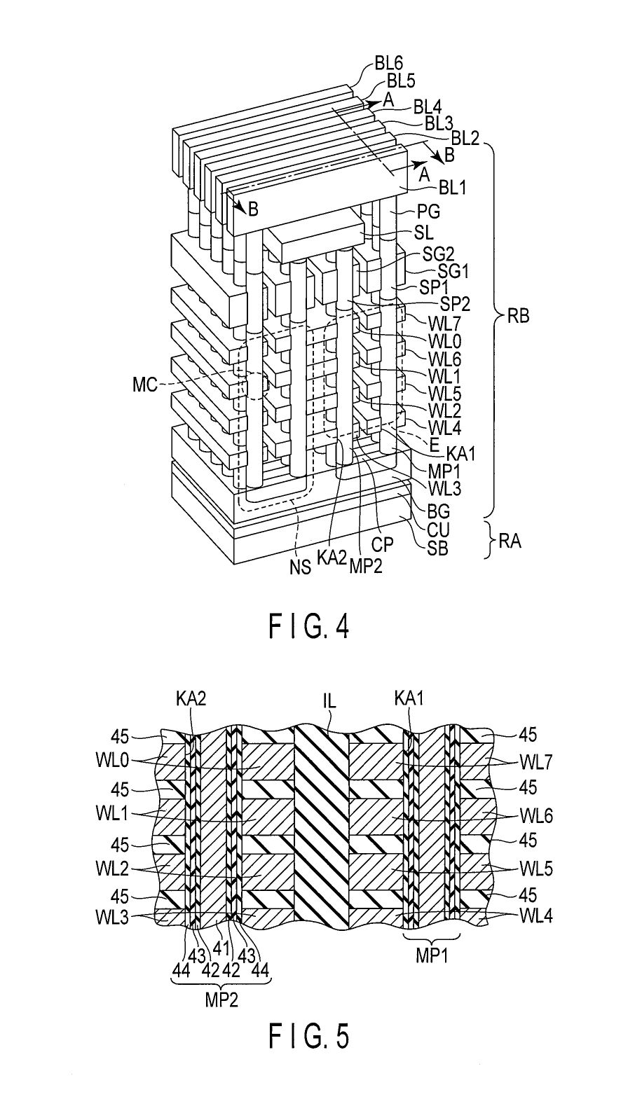

FIG. 4 shows a schematic configuration of the memory cell array 1. When memory cells X0 and SX0 are formed inside the memory cell array 1, memory cells X0 and SX0 may be configured by the NAND string shown in FIG. 4.

In FIG. 4, a NAND string NS is formed by turning up a memory cell MC in which only four layers are stacked at the lower end and connecting eight memory cells MC in series. However, the number of stacked layers of the memory cell and the number of memory cells are not limited to those in the above example.

In FIG. 3, a circuit area RA is provided on a semiconductor substrate SB and a memory area RB is provided in the circuit area RA.

In the circuit area RA, a circuit layer CU is formed on the semiconductor substrate SB. In the circuit layer CU, all or a portion of the circuit constituting the row decoder 2, the cache and sense amplifier 3, and the peripheral circuit 4 shown in FIG. 3 may be formed. The memory cell array 1 in FIG. 3 is formed in the memory cell area RB.

In the memory cell area RB, a back gate layer BG is formed on the circuit layer CU and a connection layer CP is connected to the back gate layer BG. Columnar bodies MP1 and MP2 are arranged side by side on the connection layer CP and lower ends of columnar bodies MP1 and MP2 are mutually connected via the connection layer CP.

Word lines WL3 to WL0 for four layers are successively stacked on the connection layer CP and also word lines WL4 to WL7 for four layers are successively stacked like being adjacent to word lines WL3 to WL0, respectively. The NAND string NS is configured by word lines WL4 to WL7 being passed through by columnar body MP1 and also word lines WL0 to WL3 being passed through by columnar body MP2.

Columnar bodies SP1 and SP2 are formed on columnar bodies MP1 and MP2, respectively.

A selector gate SG1 passed through by columnar body SP1 is formed above word line WL7 in the top layer and a selector gate SG2 passed through by columnar body SP2 is formed above word line WL0 in the top layer.

A source line SL connected to columnar body SP2 is provided above selector gate SG2 and bit lines BL1 to BL6 connected to columnar body SP1 via a plug PG are formed for each column above selector gate SG1. Incidentally, columnar bodies MP1 and MP2 may be arranged at intersections of bit lines BL1 to BL6 and word lines WL0 to WL7.

FIG. 5 is a sectional view showing by enlarging a dotted line E portion shown in FIG. 4.

In FIG. 5, an insulating material IL is placed between word lines WL0 to WL3 and WL4 to WL7.

An interlayer dielectric 45 is formed between word lines WL0 to WL3 and WL4 to WL7.

Word lines WL0 to WL3 and interlayer dielectric 45 have a through-hole KA2 passing through in a lamination direction thereof and word lines WL4 to WL7 and interlayer dielectric 45 have a through-hole KA1 passing through in the lamination direction thereof. Columnar body MP1 is formed inside through-hole KA1 and columnar body MP2 is formed inside through-hole KA2.

A columnar semiconductor 41 is formed in the center of columnar bodies MP1 and MP2. A tunnel insulating film 42 is formed between the inner surface of through-holes KA1 and KA2 and the columnar semiconductor 41, a charge trap layer 43 is formed between the inner surface of through-holes KA1 and KA2 and the tunnel insulating film 42, and a block insulating film 44 is formed between the inner surface of through-holes KA1 and KA2 and the charge trap layer 43.

The columnar semiconductor 41 can be formed by using a semiconductor, for example, polysilicon. The tunnel insulating film 42 and the block insulating film 44 can be formed by using, for example, silicon oxide. The charge trap layer 43 can be formed by using, for example, silicon nitride or ONO film (three-layer laminated structure of silicon oxide, silicon nitride, and silicon oxide).

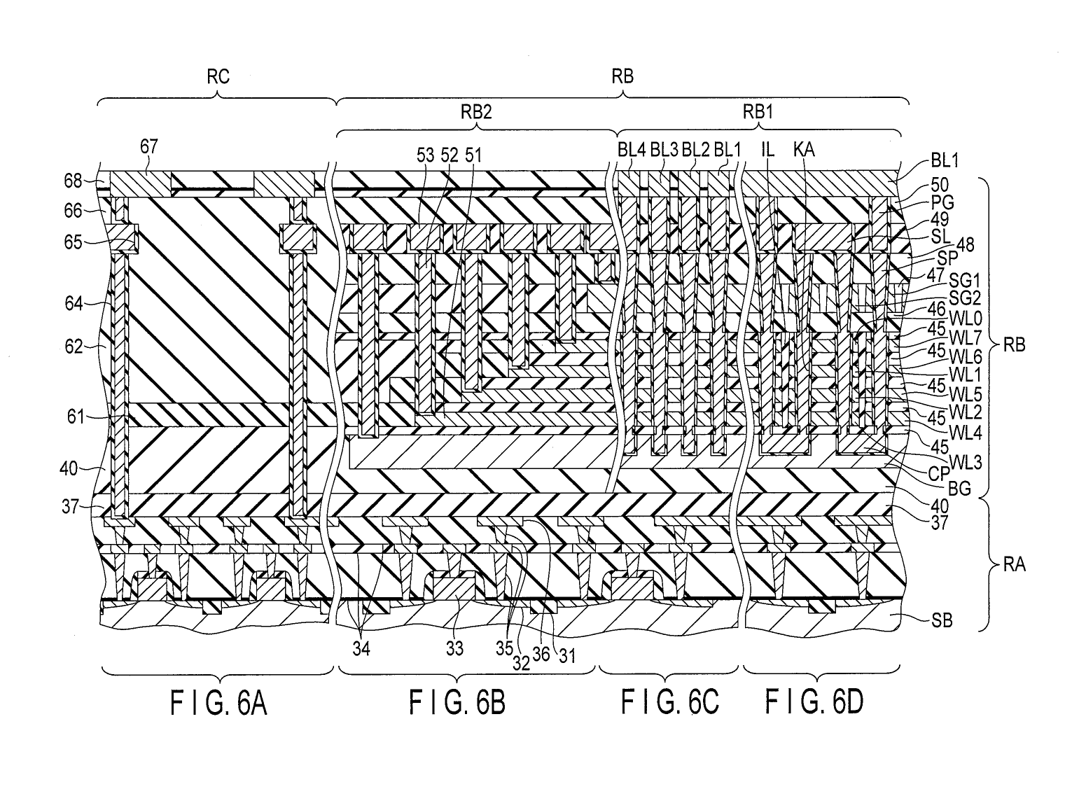

FIG. 6A is a sectional view schematically showing a peripheral circuit unit of the NAND flash memory shown in FIG. 3, FIG. 6B is a sectional view schematically showing a word line leading portion of the NAND flash memory shown in FIG. 3, FIG. 6C is a sectional view along line A-A in FIG. 4, and FIG. 6D is a sectional view along line B-B in FIG. 4.

In FIGS. 6A to 6D, a peripheral area RC is provided in a periphery of the memory area RB. Incidentally, the circuit area RA may be provided in the peripheral area RC. A memory cell area RB1 and a leading area RB2 are provided in the memory area RB. In the circuit area RA, shallow trench isolation (STI) 31 as an element isolation region is formed in the semiconductor substrate SB, a diffusion layer 32 is formed in an active area isolated by the STI 31, and a gate 33 is arranged in a channel region between the diffusion layers 32 to form a transistor.

An interlayer dielectric 34 is formed on the semiconductor substrate SB on which the transistor is formed and interlayer dielectric 34 has a plug 35 and an interconnect 36 embedded therein. Interlayer dielectrics 37, 40 are formed on the interconnect 36.

In the memory cell area RB1, the back gate layer BG is formed on interlayer dielectric 40 and the connection layer CP is formed on the back gate layer BG. Word lines WL3 to WL0 are successively stacked via interlayer dielectric 45 and also word lines WL4 to WL7 are successively stacked via interlayer dielectric 45.

Further, selector gate SG2 is formed on word line WL0 via an interlayer dielectric 46 and selector gate SG1 is formed on word line WL7 via interlayer dielectric 46. In addition, an interlayer dielectric 47 is embedded between selector gates SG1 and SG2.

Further, a source line SL is formed on selector gate SG2 via an interlayer dielectric 48 and the source line SL is embedded in an interlayer dielectric 49. In addition, a bit line BL1 is formed on selector gate SG1 and the source line SL via an interlayer dielectric 50.

Bit lines BL1 to BL4 are provided in the memory cell area RB1 and an interconnect 51, a plug 52, and an interconnect 53 connected to, for example, word lines WL4, WL5, WL6 and WL7 are provided in the leading area RB2.

In the peripheral area RC, interlayer dielectrics 61, 62 and 68 are formed on interlayer dielectric 40. Plugs 64 and 66 and interconnects 65 and 67 are embedded in interlayer dielectrics 37, 40, 61, 62 and 68.

(Test Operation of the Charge Pump Circuit)

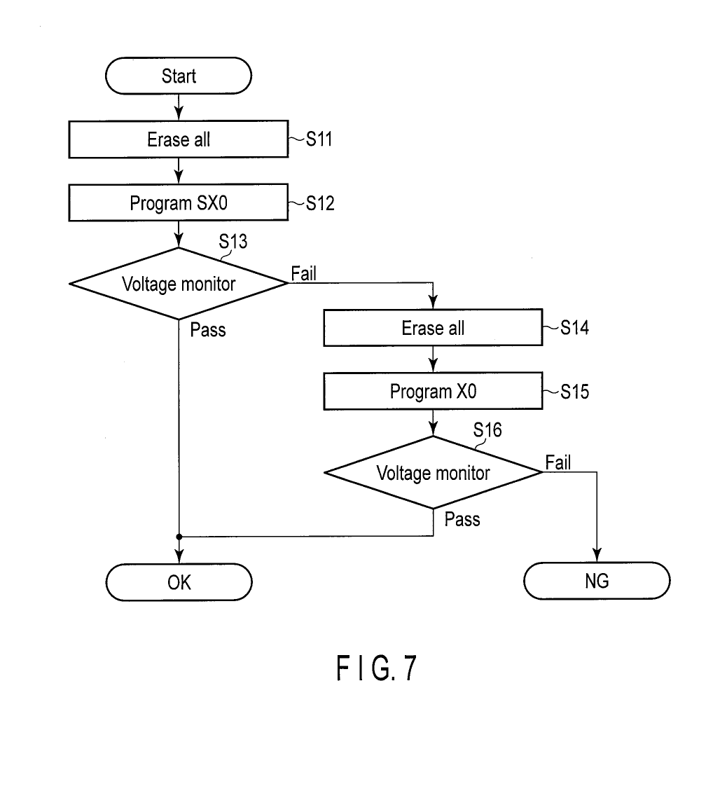

The test operation of the charge pump circuit 11 shown in FIG. 1 will be described with reference to FIG. 7.

The test of the charge pump circuit 11 is performed, for example, after a NAND flash memory is manufactured by using a tester. More specifically, the host device 22 shown in FIG. 3 is displaced to a circuit tester, for example, and a test commands are outputted from the circuit tester. The controller 21 controls NAND flash memory 10 according to the commands.

However, the test is not limited to the above case and a test function may be provided to the controller 21 of a NAND flash memory 10. In this case, the NAND flash memory can be tested by the controller 21 using commands when a defect occurs in the output voltage of the charge pump circuit after shipment.

As shown in FIG. 7, first memory cells X0 and SX0 are erased (S11). The erase operation can be performed in units of strings sharing, for example, the source line SL. When, for example, all word lines are set to the ground potential, an erasing voltage is supplied to a booster node N1 for a fixed time. Memory cells X0 and SX0 are turned on by the erase operation.

The erase operation only needs to be able to turn memory cells X0 and SX0 on and so there is no need to precisely control the threshold voltage of erasure. Therefore, verify of erasure is not necessary and there is no need to operate the cache and sense amplifier 3.

Next, spare memory cell SX0 is programmed (S12). In the present embodiment, memory cells X0 and SX0 only need to function as selector gates and so there is no need to precisely control the threshold voltage of erasure. Thus, when memory cell SX0 is programmed, program verify is not needed. Therefore, when memory cell SX0 is programmed, there is no need to drive the cache and sense amplifier 3 and memory cell SX0 may be selected by the row decoder 2 to supply a program voltage to at least one of word lines WL0 to WL7 for a fixed time.

With this program operation, the threshold voltage of memory cell SX0 is set to a predetermined level and memory cell SX0 is turned off. Thus, reserve capacitor SC0 is separated from the charge pump circuit 11 and capacitor C0 is connected to the booster node N1 of the charge pump circuit 11 via memory cell X0 which is turned on.

After the program of memory cell SX0 terminates, the charge pump circuit 11 is driven to determine whether the voltage output from the output node OUT of the charge pump circuit 11 is equal to a reference voltage (a specified voltage) or higher (S13). That is, voltage Vdd is supplied to the supply node of the power supply and a clock signal is supplied to the supply node of the clock signal to drive the charge pump circuit 11. A tester (not shown) determines whether the voltage output from the output node OUT is equal to the reference voltage or higher. If, as a result, the output voltage is equal to the reference voltage or higher, capacitor C0 is determined to be functioning normally and the test ends.

On the other hand, if the output voltage does not reach the reference voltage in step S13, capacitor C0 is determined to have a defect such as a short.

If capacitor C0 is determined to be defective, memory cells X0 and SX0 are erased again (S14).

Then, memory cell X0 is programmed (S15). Memory cell X0 is selected by the row decoder 2 and the program voltage is supplied to at least one of word lines WL0 to WL7 for a fixed time. With this program operation, the threshold voltage of memory cell X0 is set to a predetermined level and memory cell X0 is turned off. Thus, capacitor C0 is separated from the charge pump circuit 11 and spare capacitor SC0 is connected to the booster node N1 of the charge pump circuit 11 via memory cell SX0 which is turned on.

After the programming of memory cell X0 is completed, the charge pump circuit 11 is driven to determine whether the voltage output from the output node OUT of the charge pump circuit 11 is equal to a reference voltage or higher (S16). That is, voltage Vdd is supplied to the supply node of the power supply and a clock signal is supplied to the supply node of the clock signal to drive the charge pump circuit 11. A tester (not shown) determines whether the voltage output from the output node OUT is equal to the reference voltage or higher. If, as a result, the output voltage is equal to the reference voltage or higher, spare capacitor SC0 is determined to be functioning normally and the test ends.

On the other hand, if the output voltage does not reach the reference voltage in step S16, spare capacitor SC0 is also determined to have a defect such as a short. In this case, capacitor C0 and spare capacitor SC0 are defective and thus, the charge pump circuit 11 cannot be relieved by the redundant circuit and the test ends.

According to the above first embodiment, regular capacitor C0 and spare capacitor SC0 are provided and capacitor C0 and spare capacitor SC0 are allowed to be switched by memory cells X0 and SX0. Thus, when regular capacitor C0 is defective, capacitor C0 can be switched to spare capacitor SC0 so that the defect of capacitor C0 can be relieved and also yields of the charge pump circuit and semiconductor storage device can be improved.

Regular capacitor C0 and spare capacitor SC0 of the charge pump circuit 11 are formed by three-dimensionally stacking interconnects WL0 to WL7 constituting a plurality of word lines and interconnects W01 to W31 of the layers. In addition, these interconnects W01 to W31 prevent interference of lithography when the word lines are formed and thus, formed dummy interconnects can be used. Thus, there is no need to separately provide a capacitor and therefore, an increase in chip area can be prevented.

In addition, memory cells X0 and SX0 are used as selector gates to switch regular capacitor C0 and spare capacitor SC0. If, instead of memory cells, transistors are used, a read-only memory (ROM) to store data to control the transistors and a register to hold control data read from the ROM are needed. However, if, like the present embodiment, memory cells are used, neither ROM nor register needs to be provided separately. Therefore, the chip area can be reduced.

Further, if the ROM and register are used, it is necessary to read control data from the ROM and to set the control data to the register after a power only set operation during activation of a semiconductor storage device. In the present embodiment, however, data is written to memory cell X0 or memory cell SX0 in advance and thus, the setting operation after the power only set operation is not needed so that the activation speed of the semiconductor storage device can be improved.

### Second Embodiment

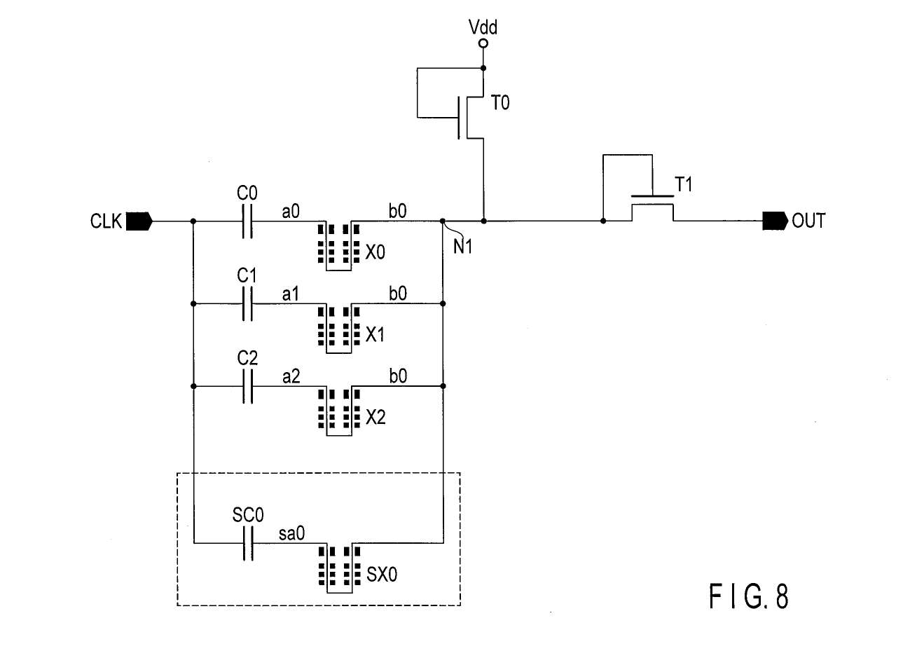

FIG. 8 shows the second embodiment and the same reference numbers are attached to the same units as those in the first embodiment to describe only different units.

The second embodiment shows an example of a charge pump circuit in which, for example, three capacitors always operate and includes three regular capacitors C0, C1 and C2, a spare capacitor SC0, and memory cells X0, X1, X2 and SX0 as selector gates to switch capacitors C0, C1, C2 and SC0.

In FIG. 8, each one end of regular capacitors C1 and C2 is connected to the supply node of a clock signal CLK. Each of the other ends of regular capacitors C1 and C2 is connected to each one end of memory cells X1 and X2 via interconnects a1 and a2, respectively. The other ends of memory cells X1 and X2 are connected to a booster node N1 of a charge pump circuit 11 via an interconnect b0.

(Test Operation of the Charge Pump Circuit)

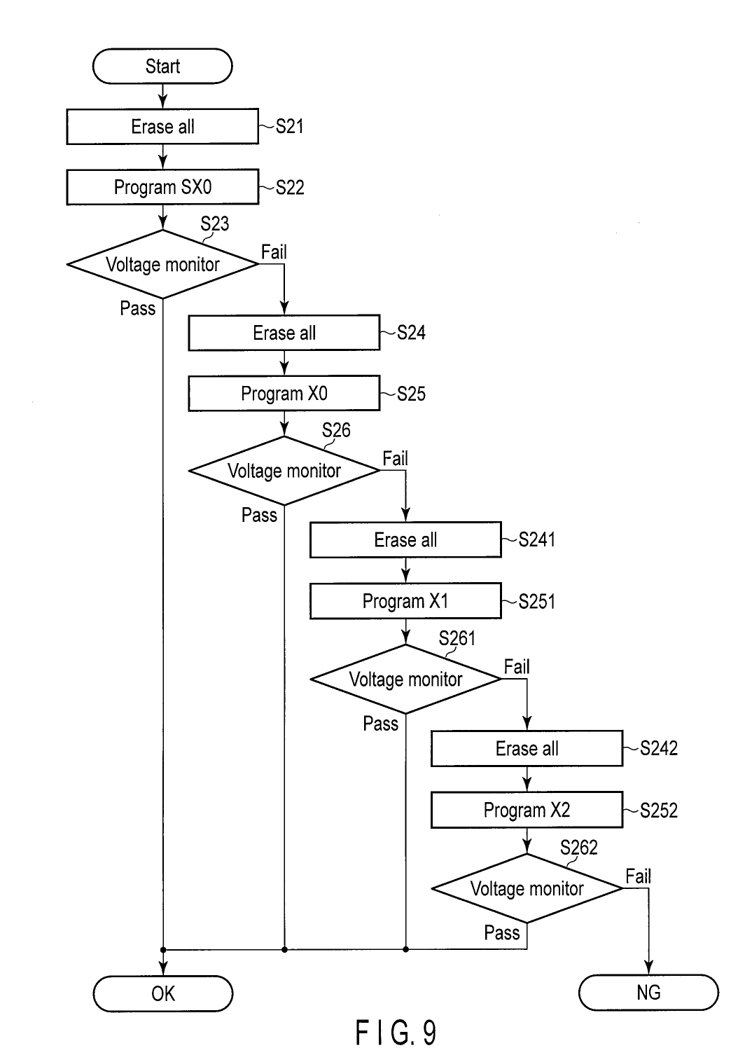

FIG. 9 shows the test operation of the charge pump circuit 11 shown in FIG. 8. The test operation is approximately the same as the test operation shown in FIG. 7.

First, all memory cells X0 to X2 and SX0 are erased (S21) and then, spare memory cell SX0 is programmed (S22).

Next, the charge pump circuit 11 is driven while capacitors C0, C1 and C2 are connected to the booster node N1 via memory cells X0, X1 and X2 to determine whether the voltage output from an output node OUT of the charge pump circuit 11 is equal to a reference voltage or higher (S23). If, as a result, the output voltage is equal to the reference voltage or higher, capacitors C0, C1 and C2 are determined to be functioning normally and the test ends.

On the other hand, if the output voltage does not reach the reference voltage in step S23, one of capacitors C0, C1 and C2 is determined to have a defect such as a short.

If one of capacitors C0, C1 and C2 is determined to be defective, all memory cells X0, X1, X2 and SX0 are erased again (S24).

Then, memory cell X0 is programmed (S25).

After the programming of memory cell X0 is completed, the charge pump circuit 11 is driven to determine whether the voltage output from the output node OUT of the charge pump circuit 11 is equal to a reference voltage or higher (S26). If, as a result, the output voltage is equal to the reference voltage or higher, regular capacitors C1 and C2 and spare capacitor SC0 are determined to be functioning normally and the test ends.

On the other hand, if the output voltage does not reach the reference voltage in step S26, one of capacitors C1 and C2 and spare capacitor SC0 is determined to have a defect such as a short.

In this case, all memory cells X0, X1, X2 and SX0 are erased again (S241) and then, memory cell X1 is programmed (S251). Next, the charge pump circuit 11 is driven to determine whether the voltage output from the output node OUT of the charge pump circuit 11 is equal to a reference voltage or higher (S261). If, as a result, the output voltage is equal to the reference voltage or higher, regular capacitors C0 and C2 and spare capacitor SC0 are determined to be functioning normally and the test ends.

On the other hand, if the output voltage does not reach the reference voltage in step S261, one of capacitors C0 and C2 and spare capacitor SC0 is determined to have a defect such as a short.

In this case, all memory cells X0, X1, X2 and SX0 are erased again (S242) and then, memory cell X2 is programmed (S252). Next, the charge pump circuit 11 is driven to determine whether the voltage output from the output node OUT of the charge pump circuit 11 is equal to a reference voltage or higher (S262). If, as a result, the output voltage is equal to the reference voltage or higher, regular capacitors C0 and C1 and spare capacitor SC0 are determined to be functioning normally and the test ends.

On the other hand, if the output voltage does not reach the reference voltage in step S262, the charge pump circuit 11 is determined to be non-relievable.

Effects similar to those according to the first embodiment can also be obtained by the second embodiment.

In addition, even if regular capacitors increase, these capacitors can be formed by lamination and therefore, an increase in chip area can be inhibited. Also in this case, the number of memory cells as selector gates increases, but the area occupied by memory cells of a chip is small and therefore, the chip area is not affected.

### Third Embodiment

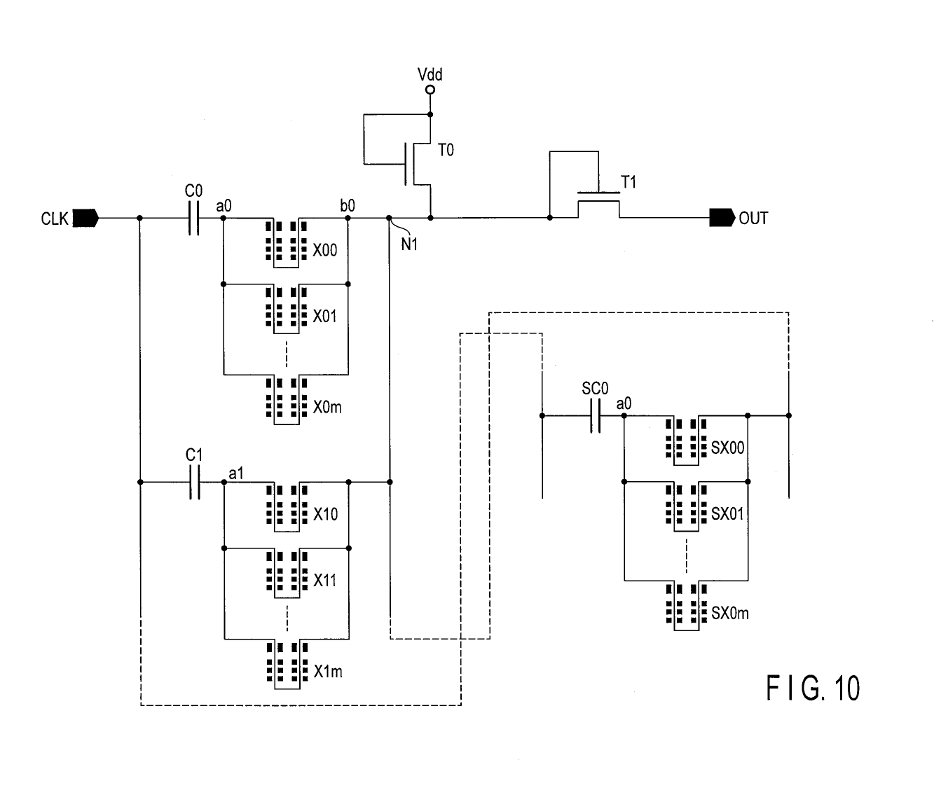

FIG. 10 shows the third embodiment.

When, as described above, memory cells are used as selector gates, the cell current tends to decrease with increasingly finer microprocessing of memory cells. If the cell current decreases in this way, the potential of a booster node N1 cannot be changed at high speed accompanying a clock signal, degrading capabilities of a charge pump circuit 11.

Thus, in the third embodiment, capability degradation of the charge pump circuit 11 is prevented by connecting a plurality of memory cells in parallel to increase a substantial cell current.

As shown in FIG. 10, a plurality of memory cells X00, X01, . . . , X0m is connected in parallel between, for example, the other end of a capacitor C0 and the booster node N1 and a plurality of memory cells X10, X11, . . . , X1m is connected in parallel between the other end of a capacitor C1 and the booster node N1. Further, a plurality of memory cells SX00, SX01, . . . , SX0m is connected in parallel between the other end of a capacitor SC0 and the booster node N1.

(Test Operation of the Charge Pump Circuit)

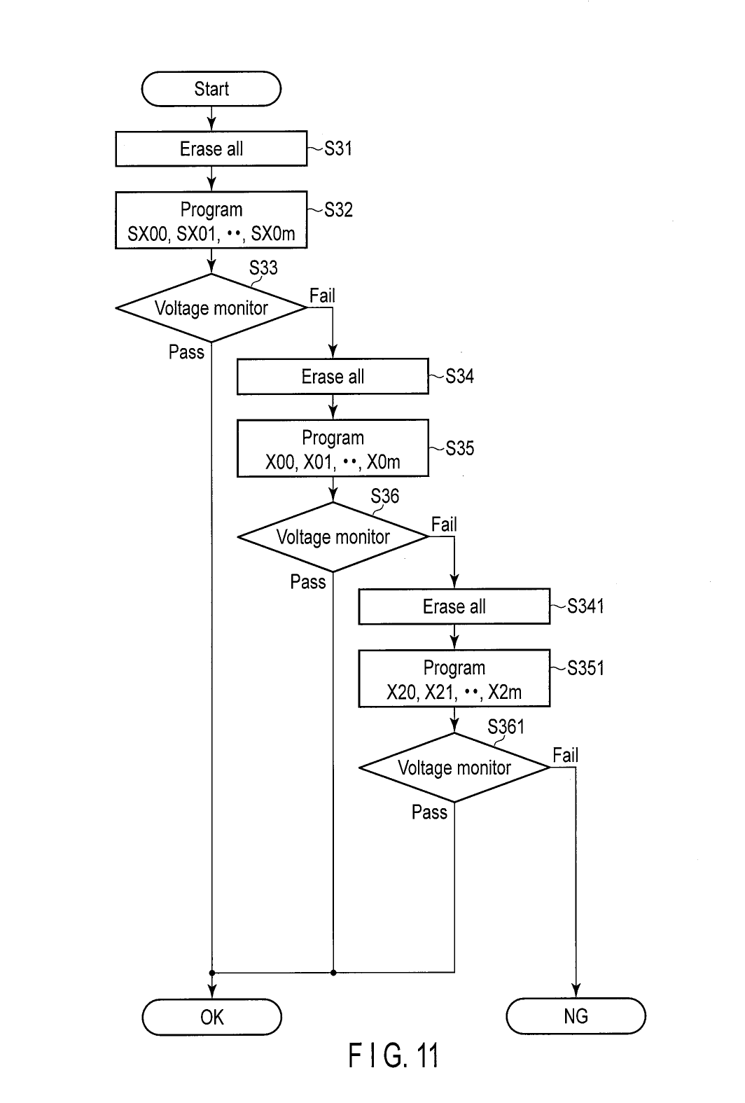

FIG. 11 shows the test operation of the charge pump circuit 11 shown in FIG. 10. The test operation is approximately the same as the test operation shown in FIG. 9.

First, all memory cells X00, X01, . . . , X0m, X10, X11, . . . , X1m, SX00, SX01, . . . , SX0m are erased (S31) and then, spare memory cells SX00, SX01, . . . , SX0m are programmed (S32).

Next, the charge pump circuit 11 is driven while capacitors C0 and C1 are connected to the booster node N1 via memory cells X00, X01, . . . , X0m, X10, X11, . . . , X1m to determine whether the voltage output from an output node OUT of the charge pump circuit 11 is equal to a reference voltage or higher (S33). If, as a result, the output voltage is equal to the reference voltage or higher, capacitors C0 and C1 are determined to be functioning normally and the test ends.

On the other hand, if the output voltage does not reach the reference voltage in step S33, one of capacitors C0 and C1 is determined to have a defect such as a short.

If one of capacitors C0 and C1 is determined to be defective, all memory cells X00, X01, . . . , X0m, X10, X11, . . . , X1m, SX00, SX01, . . . , SX0m are erased again (S34).

Then, memory cells X00, X01, . . . , X0m are programmed (S35).

After the programming of memory cells X00, X01, . . . , X0m are completed, the charge pump circuit 11 is driven to determine whether the voltage output from the output node OUT of the charge pump circuit 11 is equal to a reference voltage or higher (S36). If, as a result, the output voltage is equal to the reference voltage or higher, regular capacitor C1 and spare capacitor SC0 are determined to be functioning normally and the test ends.

On the other hand, if the output voltage does not reach the reference voltage in step S36, one of capacitor C1 and spare capacitor SC0 is determined to have a defect such as a short.

In this case, all memory cells X00, X01, . . . , X0m, X10, X11, . . . , X1m, SX00, SX01, . . . , SX0m are erased again (S341) and then, memory cells X10, X11, . . . , X1m are programmed (S351). Next, the charge pump circuit 11 is driven to determine whether the voltage output from the output node OUT of the charge pump circuit 11 is equal to a reference voltage or higher (S361). If, as a result, the output voltage is equal to the reference voltage or higher, regular capacitor C0 and spare capacitor SC0 are determined to be functioning normally and the test ends.

On the other hand, if the output voltage does not reach the reference voltage in step S361, the charge pump circuit 11 is determined to be non-relievable.

Effects similar to those according to the first and second embodiments can also be obtained by the third embodiment.

In addition, a plurality of memory cells is connected in parallel to each of capacitors C0, C1 and SC0 and thus, a substantial cell current can be increased. Therefore, the potential of the booster node can be changed at high speed and the effectiveness of the charge pump circuit 11 can be improved.

Also in this case, the number of memory cells as selector gates increases, but the area occupied by memory cells of a chip is small and therefore, the chip area is not affected.

In the first to third embodiments, memory cells arranged in the memory cell array 1 are used as memory cells used for the charge pump circuit 11, but the embodiments are not limited to such an example and, for example, the diameter of a through-hole of memory cells of the memory cell array 1 can be changed. That is, the cell current of memory cells for the charge pump circuit 11 can be increased by making the diameter of the through-hole of memory cells in the charge pump circuit 11 larger than the diameter of the through-hole of memory cells in the memory cell array 1.

If the length of an interconnect a0 between a capacitor and a memory cell and the length of an interconnect b0 between a memory cell and a booster node are long, the interconnect resistance of these interconnects increases and the rise time and fall time of a signal become longer so that a charge pump circuit does not operate normally. Thus, the lengths of interconnects a0 and b0 can be reduced by arranging memory cells for the charge pump circuit 11 in a region close to a peripheral circuit 4 shown in FIG. 3 or inside the peripheral circuit 4.

It should be noted that the configuration of the memory cell array 1 is described in, for example, U.S. patent application Ser. No. 12/407,403, “Three-dimensional Laminated Nonvolatile Semiconductor Memory,” filed Mar. 19, 2009. In addition, the configuration of the memory cell array 1 is described in U.S. patent application Ser. No. 12/406,524, “Three-dimensional Laminated Nonvolatile Semiconductor Memory,” filed Mar. 18, 2009; U.S. patent application Ser. No. 12/679,991, “Nonvolatile Semiconductor Storage Device and Manufacturing Method Thereof,” filed Mar. 25, 2010; and U.S. patent application Ser. No. 12/532,030, “Semiconductor Memory and Manufacturing Method Thereof,” filed Mar. 23, 2009. These patent applications are incorporated herein in their entirety by reference.

The term “connect” is used in either the detailed description or the claims. The “connect” is defined as electrically being connected, and indicates being connected directly or being indirectly connected by any particular element.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a first capacitor including first and second ends, the first end being electrically connected to an input end of a clock signal;
a second capacitor including third and fourth ends and electrically connected to the input end to serve as a spare;
a first selector gate electrically connected between the second end of the first capacitor and a first node of a voltage generating circuit; and
a second selector gate connected between the fourth end of the second capacitor and the first node, wherein
the first and second selector gates are switched based on an output voltage of the voltage generating circuit.

2. The device according to claim 1, wherein
the first and second selector gates are nonvolatile first and second memory cells.

3. The device according to claim 2, wherein
the first and second memory cells are memory cells stacked above a semiconductor substrate.

4. The device according to claim 3, further comprising:
first to fourth word lines, wherein
the first capacitor is configured by the first and second word lines and first and second interconnect layers in same layers and the second capacitor is configured by the third and fourth word lines and third and fourth interconnect layers in the same layers.

5. The device according to claim 4, wherein
the first and second memory cells are erased and subsequently, the second memory cell is programmed and then, the output voltage of the voltage generating circuit is determined, wherein if the output voltage is lower than a reference voltage, the first and second memory cells are erased and subsequently, the first memory cell is programmed and then, the output voltage of the voltage generating circuit is determined.

6. The device according to claim 3, wherein
the first capacitor is configured by a plurality of third capacitors and
the first selector gate is configured by a plurality of third memory cells.

7. The device according to claim 6, wherein
the third memory cells and the second memory cell are erased and subsequently, the second memory cell is programmed and then, the output voltage of the voltage generating circuit is determined, wherein if the output voltage is lower than a reference voltage, the third memory cells and the second memory cell are erased and subsequently, one of the third memory cells is programmed and then, the output voltage of the voltage generating circuit is determined.

8. The device according to claim 3, wherein
the first selector gate is configured by a plurality of fourth memory cells and
the second selector gate is configured by a plurality of fifth memory cells.

9. The device according to claim 8, wherein
the fourth memory cells and the fifth memory cells are erased and subsequently, the fifth memory cells is programmed and then, the output voltage of the voltage generating circuit is determined, wherein if the output voltage is lower than a reference voltage, the fourth memory cells and the fifth memory cells are erased and subsequently, the fourth memory cells is programmed and then, the output voltage of the voltage generating circuit is determined.

10. The device according to claim 9, wherein
the first to fifth memory cells are arranged in a memory cell array of a NAND flash memory.

11. The device according to claim 9, wherein
the first to fifth memory cells are arranged in a peripheral circuit area of a NAND flash memory.

12. A semiconductor storage device comprising:
a memory cell array including a plurality of memory cells stacked above a semiconductor substrate;
a plurality of word lines electrically connected to each of the memory cells;
a voltage generating circuit configured to generate a voltage supplied to the memory cells;
a first capacitor including first and second ends, the first end being electrically connected to an input end of a clock signal;
a second capacitor including third and fourth ends and electrically connected to the input end to serve as a spare;
a first selector gate electrically connected between the second end of the first capacitor and a first node of the voltage generating circuit; and
a second selector gate connected between the fourth end of the second capacitor and the first node, wherein
the first and second selector gates are switched based on an output voltage of the voltage generating circuit.

13. The device according to claim 12, wherein
the first and second selector gates are nonvolatile first and second memory cells.

14. The device according to claim 13, wherein
the first and second memory cells are memory cells stacked above a semiconductor substrate.

15. The device according to claim 14, wherein
the word lines contains first to fourth word lines and
the first capacitor is configured by the first and second word lines and first and second interconnect layers in same layers and the second capacitor is configured by the third and fourth word lines and third and fourth interconnect layers in the same layers.

16. The device according to claim 14, wherein
the first capacitor is configured by a plurality of third capacitors and
the first selector gate is configured by a plurality of third memory cells.

17. The device according to claim 16, wherein
the first selector gate is configured by a plurality of fourth memory cells and
the second selector gate is configured by a plurality of fifth memory cells.

18. The device according to claim 14, wherein
the first and second memory cells are erased and subsequently, the second memory cell is programmed and then, the output voltage of the voltage generating circuit is determined, wherein if the output voltage is lower than a reference voltage, the first and second memory cells are erased and subsequently, the first memory cell is programmed and then, the output voltage of the voltage generating circuit is determined.

19. The device according to claim 16, wherein
the third memory cells and the second memory cell are erased and subsequently, the second memory cell is programmed and then, the output voltage of the voltage generating circuit is determined, wherein if the output voltage is lower than a reference voltage, the third memory cells and the second memory cell are erased and subsequently, one of the third memory cells is programmed and then, the output voltage of the voltage generating circuit is determined.

20. The device according to claim 17, wherein
the fourth memory cells and the fifth memory cells are erased and subsequently, the fifth memory cells is programmed and then, the output voltage of the voltage generating circuit is determined, wherein if the output voltage is lower than a reference voltage, the fourth memory cells and the fifth memory cells are erased and subsequently, the fourth memory cells is programmed and then, the output voltage of the voltage generating circuit is determined.
